(19) United States
(12) Patent Application Publication
(10) Pub. No.: US 2018/0175073 A1
(43) Pub. Date: Jun. 21, 2018

(54) ARRAY SUBSTRATE, MANUFACTURING METHOD THEREOF AND DISPLAY DEVICE

(71) Applicants: BOE TECHNOLOGY GROUP CO., LTD., Beijing (CN); CHONGQING BOE OPTOELECTRONICS TECHNOLOGY CO., LTD., Chongqing (CN)

(72) Inventor: Qian Wang, Beijing (CN)

(21) Appl. No.: 15/722,942

(22) Filed: Oct. 2, 2017

(30) Foreign Application Priority Data
Dec. 21, 2016 (CN) 201611189759.4

(51) Int. Cl. H01L 27/12; H01L 29/66; H01L 29/786; H01L 29/24

(52) U.S. Cl. CPC H01L 27/1225; H01L 29/66969; H01L 29/7869; H01L 29/66765; H01L 29/24; H01L 29/42384; H01L 27/1262; H01L 29/78669; H01L 29/78678; H01L 27/1229; H01L 27/124; H01L 27/127

(57) ABSTRACT

An array substrate, a manufacturing method thereof and a display device are provided. The array substrate includes a display region and a GOA region. The method includes forming an active layer of a first TFT at the display region with a metal oxide semiconductor material; and forming an active layer of a second TFT at the GOA region with a non-metal oxide semiconductor layer.

### CROSS-REFERENCE TO RELATED APPLICATION

The present application claims the priority of Chinese patent application No. 201611189759.4 filed on Dec. 21, 2016, which is incorporated herein by reference in its entirety.

### TECHNICAL FIELD

The present disclosure relates to the field of display technology, in particular to an array substrate, a manufacturing method thereof and a display device.

### BACKGROUND

Currently, along with the development of display technology, in order to improve product competitiveness, a display product is provided with higher and higher resolution, up to 4K or even 8K. In addition, in order to reduce the manufacturing cost of the display product, a Gate Driver on Array (GOA) technology has been widely used. The GOA technology refers to the formation of a gate scanning driving circuit onto a thin film transistor (TFT) array substrate through a manufacturing process of a TFT, so as to perform a progressive scanning operation, and due to such advantages as low manufacturing cost and being capable of achieving a narrow-bezel design, the GOA technology has been used for various display products.

In the case that the display product has a very high resolution, there may be thousands of rows of pixels, and a charging time for the pixels in each row may be very short. In the case that an active layer of the TFT is made of amorphous silicon (a-Si), due to relatively small mobility of a-Si, it is very difficult to meet a requirement on a charging rate of the display product. Mobility of a metal oxide semiconductor is far greater than a-Si, so it may meet the requirement on the charging rate of the high-resolution display product easily. However, in the case that the metal oxide semiconductor is used as the active layer of the TFT, a threshold voltage Vth of the TFT may be drifted seriously under the effect of long-term bias, so characteristics of the TFT may change and thereby it is impossible for a GOA unit to achieve a normal scanning function. In a word, the GOA technology cannot be applied to the conventional high-resolution display product.

### SUMMARY

An object of the present disclosure is to provide an array substrate, a manufacturing method thereof, and a display device, so as to apply the GOA technology to the high-resolution display device.

In one aspect, the present disclosure provides in some embodiments a method for manufacturing an array substrate, the array substrate including a display region and a GOA region, and the method including steps of: forming an active layer of a first TFT at the display region with a metal oxide semiconductor material; and forming an active layer of a second TFT at the GOA region with a non-metal oxide semiconductor layer.

In a possible embodiment of the present disclosure, the method further includes: providing a base substrate; depositing a gate metal layer onto the base substrate, and patterning the gate metal layer so as to form a gate electrode of the first TFT and a gate electrode of the second TFT; forming a gate insulation layer; depositing a non-metal oxide semiconductor layer onto the gate insulation layer, and patterning the non-metal oxide semiconductor layer so as to form the active layer of the second TFT; depositing a metal oxide semiconductor layer onto the gate insulation layer, and patterning the metal oxide semiconductor layer so as to form the active layer of the first TFT; and depositing a source-drain metal layer onto the base substrate with the active layer of the first TFT and the active layer of the second TFT, and patterning the source-drain metal layer so as to form a source electrode and a drain electrode of the first TFT and a source electrode and a drain electrode of the second TFT.

In a possible embodiment of the present disclosure, the method further includes: providing a base substrate; depositing a gate metal layer onto the base substrate, and patterning the gate metal layer so as to form a gate electrode of the first TFT and a gate electrode of the second TFT; forming a gate insulation layer; depositing a metal oxide semiconductor layer onto the gate insulation layer, and patterning the metal oxide semiconductor layer so as to form the active layer of the first TFT; depositing a non-metal oxide semiconductor layer onto the gate insulation layer, and patterning the non-metal oxide semiconductor layer so as to form the active layer of the second TFT; and depositing a source-drain metal layer onto the base substrate with the active layer of the first TFT and the active layer of the second TFT, and patterning the source-drain metal layer so as to form a source electrode and a drain electrode of the first TFT and a source electrode and a drain electrode of the second TFT.

In a possible embodiment of the present disclosure, the method further includes: providing a base substrate; depositing a buffer layer onto the base substrate; depositing a non-metal oxide semiconductor layer onto the buffer layer, and patterning the non-metal oxide semiconductor layer so as to form the active layer of the second TFT; depositing a metal oxide semiconductor layer onto the buffer layer, and patterning the metal oxide semiconductor layer so as to form the active layer of the first TFT; depositing a source-drain metal layer onto the base substrate with the active layer of the first TFT and the active layer of the second TFT, and patterning the source-drain metal layer so as to form a source electrode and a drain electrode of the first TFT and a source electrode and a drain electrode of the second TFT; forming a gate insulation layer; and depositing a gate metal layer onto the gate insulation layer, and patterning the gate metal layer so as to form a gate electrode of the first TFT and a gate electrode of the second TFT.

In a possible embodiment of the present disclosure, the method further includes: providing a base substrate; depositing a buffer layer onto the base substrate; depositing a metal oxide semiconductor layer onto the buffer layer, and patterning the metal oxide semiconductor layer so as to form the active layer of the first TFT; depositing a non-metal oxide semiconductor layer onto the buffer layer, and patterning the non-metal oxide semiconductor layer so as to form the active layer of the second TFT; depositing a source-drain metal layer onto the base substrate with the active layer of the first TFT and the active layer of the second TFT, and patterning the source-drain metal layer so as to form a source electrode and a drain electrode of the first TFT and a source electrode and a drain electrode of the second TFT; forming a gate insulation layer; and depositing a gate metal layer onto the gate insulation layer, and patterning the gate metal layer so as to form a gate electrode of the first TFT and a gate electrode of the second TFT.

In a possible embodiment of the present disclosure, the non-metal oxide semiconductor material is polycrystalline silicon (p-Si) or a-Si, and the metal oxide semiconductor material is indium gallium zinc oxide (IGZO), indium zinc oxide (IZO), zinc oxynitride (ZnON), copper oxide (CuO) or tin oxide (SnO).

In another aspect, the present disclosure provides in some embodiments an array substrate manufactured by the above-mentioned method, including a display region and a GOA region. An active layer of a first TFT at the display region is made of a metal oxide semiconductor material, and an active layer of a second TFT at the GOA region is made of a non-metal oxide semiconductor material.

In a possible embodiment of the present disclosure, the array substrate further includes: a base substrate; a gate electrode of the first TFT and a gate electrode of the second TFT arranged on the base substrate; a gate insulation layer; the active layer of the first TFT and the active layer of the second TFT arranged on the gate insulation layer; and a source electrode and a drain electrode of the first TFT and a source electrode and a drain electrode of the second TFT.

In a possible embodiment of the present disclosure, the array substrate further includes: a base substrate; a buffer layer arranged on the base substrate; the active layer of the first TFT and the active layer of the second TFT arranged on the buffer layer; a source electrode and a drain electrode of the first TFT and a source electrode and a drain electrode of the second TFT; a gate insulation layer; and a gate electrode of the first TFT and a gate electrode of the second TFT arranged on the gate insulation layer.

In yet another aspect, the present disclosure provides in some embodiments a display device including the above-mentioned array substrate.

According to the embodiments of the present disclosure, the active layer of the TFT at the display region of the array substrate and the active layer of the TFT at the GOA region are made of different materials. To be specific, the active layer of the TFT at the display region of the array substrate is made of the metal oxide semiconductor material. In this way, in the case that a display product has a very high resolution, it is still able to meet a requirement on a charging rate of the high-resolution display product due to high mobility of the metal oxide semiconductor material. The active layer of the TFT at the GOA region of the array substrate is made of the non-metal oxide semiconductor material. In this way, it is able to prevent the occurrence of Vth drift for the TFT due to long-term bias, thereby to prevent a characteristic of the TFT from being varied and ensure a normal scanning function of a GOA unit. Hence, it is able to apply a GOA technology to the high-resolution display device.

### BRIEF DESCRIPTION OF THE DRAWINGS

FIG. 1 is a schematic view showing a bottom-gate array substrate according to one embodiment of the present disclosure;

FIG. 2 is a schematic view showing the array substrate where a gate electrode of a first TFT and a gate electrode of a second TFT are formed on a base substrate according to one embodiment of the present disclosure;

FIG. 3 is a schematic view showing the array substrate after forming a gate insulation layer according to one embodiment of the present disclosure;

FIG. 4 is a schematic view showing the array substrate where an active layer of the first TFT is firstly formed on the base substrate according to one embodiment of the present disclosure;

FIG. 5 is a schematic view showing the array substrate where the active layer of the first TFT and an active layer of the second TFT are formed on the base substrate according to one embodiment of the present disclosure;

FIG. 6 is a schematic view showing the array substrate where the active layer of the second TFT is firstly formed on the base substrate according to one embodiment of the present disclosure; and

FIG. 7 is a schematic view showing a top-gate array substrate according to one embodiment of the present disclosure.

### DETAILED DESCRIPTION

The present disclosure will be described hereinafter in conjunction with the drawings and embodiments. The following embodiments are for illustrative purposes only, but shall not be used to limit the scope of the present disclosure.

An object of the present disclosure is to provide an array substrate, a manufacturing method thereof and a display device, so as to apply a GOA technology to the high-resolution display device.

### First Embodiment

The present disclosure provides in this embodiment a method for manufacturing an array substrate. The array substrate includes a display region and a GOA region. The method includes steps of: forming an active layer of a first TFT at the display region through a metal oxide semiconductor material; and forming an active layer of a second TFT at the GOA region through a non-metal oxide semiconductor layer.

According to the method in this embodiment of the present disclosure, the active layer of the TFT at the display region of the array substrate and the active layer of the TFT at the GOA region are made of different materials. To be specific, the active layer of the TFT at the display region of the array substrate is made of the metal oxide semiconductor material. In this way, in the case that a display product has a very high resolution, it is still able to meet a requirement on a charging rate of the high-resolution display product due to high mobility of the metal oxide semiconductor material. The active layer of the TFT at the GOA region of the array substrate is made of the non-metal oxide semiconductor material. In this way, it is able to prevent the occurrence of Vth drift for the TFT due to long-term bias, thereby to prevent a characteristic of the TFT from being varied and ensure a normal scanning function of a GOA unit. Hence, it is able to apply a GOA technology to the high-resolution display device.

During the implementation, for the array substrate of a bottom-gate type, the active layer of the TFT at the GOA region may be formed prior to the active layer of the TFT at the display region. At this time, the method includes: providing a base substrate; depositing a gate metal layer onto the base substrate, and patterning the gate metal layer so as to form a gate electrode of the first TFT and a gate electrode of the second TFT; forming a gate insulation layer; depositing a non-metal oxide semiconductor layer onto the gate insulation layer, and patterning the non-metal oxide semiconductor layer so as to form the active layer of the second TFT; depositing a metal oxide semiconductor layer onto the gate insulation layer, and patterning the metal oxide semiconductor layer so as to form the active layer of the first TFT; and depositing a source-drain metal layer onto the base substrate with the active layer of the first TFT and the active layer of the second TFT, and patterning the source-drain metal layer so as to form a source electrode and a drain electrode of the first TFT and a source electrode and a drain electrode of the second TFT.

During the implementation, for the array substrate of a bottom-gate type, the active layer of the TFT at the display region may be formed prior to the active layer of the TFT at the GOA region. At this time, the method includes: providing a base substrate; depositing a gate metal layer onto the base substrate, and patterning the gate metal layer so as to form a gate electrode of the first TFT and a gate electrode of the second TFT; forming a gate insulation layer; depositing a metal oxide semiconductor layer onto the gate insulation layer, and patterning the metal oxide semiconductor layer so as to form the active layer of the first TFT; depositing a non-metal oxide semiconductor layer onto the gate insulation layer, and patterning the non-metal oxide semiconductor layer so as to form the active layer of the second TFT; and depositing a source-drain metal layer onto the base substrate with the active layer of the first TFT and the active layer of the second TFT, and patterning the source-drain metal layer so as to form a source electrode and a drain electrode of the first TFT and a source electrode and a drain electrode of the second TFT.

During the implementation, for the array substrate of a top-gate type, the active layer of the TFT at the GOA region may be formed, then the active layer of the TFT at the display region is formed. At this time, the method includes: providing a base substrate; depositing a buffer layer onto the base substrate; depositing a non-metal oxide semiconductor layer onto the buffer layer, and patterning the non-metal oxide semiconductor layer so as to form the active layer of the second TFT; depositing a metal oxide semiconductor layer onto the buffer layer, and patterning the metal oxide semiconductor layer so as to form the active layer of the first TFT; depositing a source-drain metal layer onto the base substrate with the active layer of the first TFT and the active layer of the second TFT, and patterning the source-drain metal layer so as to form a source electrode and a drain electrode of the first TFT and a source electrode and a drain electrode of the second TFT; forming a gate insulation layer; and depositing a gate metal layer onto the gate insulation layer, and patterning the gate metal layer so as to form a gate electrode of the first TFT and a gate electrode of the second TFT.

During the implementation, for the array substrate of a top-gate type, the active layer of the TFT at the display region may be formed, and then the active layer of the TFT at the GOA region is formed. At this time, the method includes: providing a base substrate; depositing a buffer layer onto the base substrate; depositing a metal oxide semiconductor layer onto the buffer layer, and patterning the metal oxide semiconductor layer so as to form the active layer of the first TFT; depositing a non-metal oxide semiconductor layer onto the buffer layer, and patterning the non-metal oxide semiconductor layer so as to form the active layer of the second TFT; depositing a source-drain metal layer onto the base substrate with the active layer of the first TFT and the active layer of the second TFT, and patterning the source-drain metal layer so as to form a source electrode and a drain electrode of the first TFT and a source electrode and a drain electrode of the second TFT; forming a gate insulation layer; and depositing a gate metal layer onto the gate insulation layer, and patterning the gate metal layer so as to form a gate electrode of the first TFT and a gate electrode of the second TFT.

In a possible embodiment of the present disclosure, the non-metal oxide semiconductor material is p-Si or a-Si, and the metal oxide semiconductor material is IGZO, IZO, ZnON, CuO or SnO.

### Second Embodiment

The method will be described hereinafter in more details by taking the bottom-gate array substrate as an example.

The method in this embodiment may include the following steps.

Step 1: as shown in FIG. 2, providing a base substrate 1, and forming patterns of a gate electrode 2 of the TFT at the display region, a gate electrode 7 of the TFT at the GOA region and a gate line on the base substrate 1.

The base substrate may be a glass substrate or a quartz substrate. To be specific, a gate metal layer having a thickness of about 500 to 4000 Å may be deposited onto the base substrate 1 through sputtering or thermal evaporation. The gate metal layer may be made of Cu, Al, Ag, Mo, Cr, Nd, Ni, Mn, Ti, Ta, W or an alloy thereof, and it may be of a single-layered structure or a multi-layered structure such as Cu/Mo, Ti/Cu/Ti or Mo/Al/Mo. Next, a photoresist may be applied onto the gate metal layer and then exposed through a mask plate, so as to form a photoresist reserved region corresponding to a region where the patterns of the gate line and the gate electrodes are located and a photoresist unreserved region corresponding a region other than the above region. Next, the photoresist may be developed, so as to fully remove the photoresist at the photoresist unreserved region, and maintain a thickness of the photoresist at the photoresist reserved region. Finally, a gate metal film at the photoresist unreserved region may be fully etched off through an etching process, and the remaining photoresist may be removed, so as to form the patterns of the gate electrode 2 of the TFT at the display region, the gate electrode 7 of the TFT at the GOA region and the gate line.

Step 2: as shown in FIG. 3, forming a gate insulation layer 3 on the base substrate 1 acquired after Step 1.

To be specific, the gate insulation layer 3 having a thickness of about 500 to 5000 Å may be deposited onto the base substrate acquired after Step 1 through Plasma Enhanced Chemical Vapor deposition (PECVD). The gate metal layer 3 may be made of oxide, nitride or oxynitride, and reactive gases may be SiH₄, NH₃ or N₂, or SiH₂Cl₂, NH₃ or N₂.

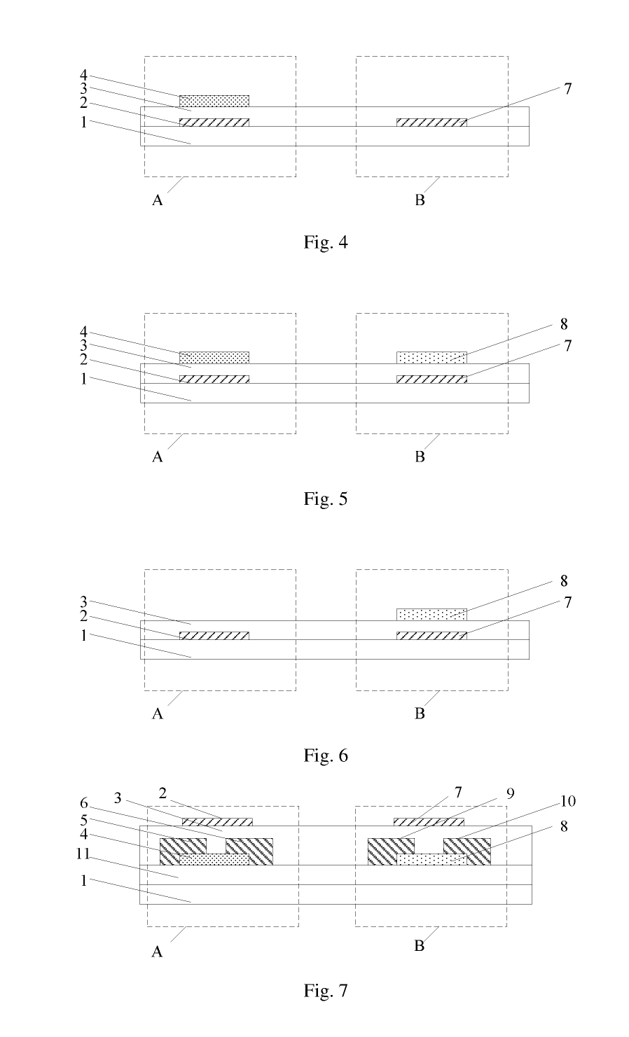

Step 3: as shown in FIG. 4, depositing a metal oxide semiconductor layer onto the gate insulation layer 3, and patterning the metal oxide semiconductor layer so as to form an active layer 4 of the TFT at the display region.

To be specific, a layer of a metal oxide semiconductor material may be deposited onto the gate insulation layer 3, and the metal oxide semiconductor material may be IGZO, IZO, ZnON, CuO or SnO. Next, a photoresist may be applied to the layer of the metal oxide semiconductor material, and then exposed through a half-tone or grey-tone mask plate, so as to form a photoresist fully-reserved region corresponding to a region where the active layer 4 of the TFT at the display region is located, and a photoresist unreserved region corresponding to a region other than the above region. Next, the photoresist may be developed, so as to fully remove the photoresist at the photoresist unreserved region, and maintain a thickness of the photoresist at the photoresist fully-reserved region. Finally, the metal oxide semiconductor material at the photoresist unreserved region may be fully etched off through an etching process, and the remaining photoresist may be removed, so as to form the pattern of the active layer 4 of the TFT at the display region.

Step 4: as shown in FIG. 5, depositing a non-metal oxide semiconductor layer onto the gate insulation layer 3, and patterning the non-metal oxide semiconductor layer so as to form an active layer 8 of the TFT at the GOA region.

To be specific, a layer of a non-metal oxide semiconductor material may be deposited onto the gate insulation layer 3, and the non-metal oxide semiconductor material may be p-Si or a-Si. Next, a photoresist may be applied onto the non-metal oxide semiconductor material, and then exposed through a half-tone or grey-tone mask plate, so as to form a photoresist fully-reserved region corresponding to a region where the active layer 8 of the TFT at the GOA region is located, and a photoresist unreserved region corresponding to a region other than the above region. Next, the photoresist may be developed, so as to fully remove the photoresist at the photoresist unreserved region, and maintain a thickness of the photoresist at the photoresist fully-reserved region. Finally, the non-metal oxide semiconductor material at the photoresist unreserved region may be fully etched off through an etching process and remove the remaining photoresist, so as to form a pattern of the active layer 8 of the TFT at the GOA region.

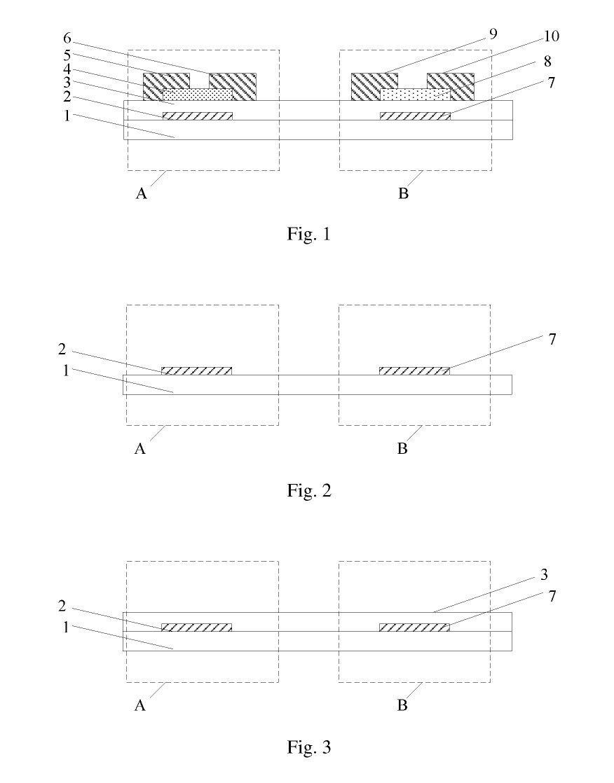

Step 5: as shown in FIG. 1, forming a source electrode 5 and a drain electrode 6 of the TFT at the display region and a source electrode 9 and a drain electrode 10 of the TFT at the GOA region and a data line on the base substrate 1 acquired after Step 4.

To be specific, a source-drain metal layer having a thickness of about 2000 to 4000 Å may be deposited onto the base substrate 1 acquired after Step 4 through magnetron sputtering, thermal evaporation or any other film-forming method. The source-drain metal layer may be made of Cu, Al, Ag, Mo, Cr, Nd, Ni, Mn, Ti, Ta or W, or an alloy thereof, and it may be of a single-layered structure or a multi-layered structure such as Cu/Mo, Ti/Cu/Ti or Mo/Al/Mo. Next, a photoresist may be applied to the source-drain metal layer and then exposed through a mask plate, so as to form a photoresist reserved region corresponding to a region where patterns of the source electrodes, the drain electrodes and the data line are located, and a photoresist unreserved region corresponding to a region other than the above region. Next, the photoresist may be developed, so as to fully remove the photoresist at the photoresist unreserved region and maintain a thickness of the photoresist at the photoresist reserved region. Finally, the source-drain metal layer at the photoresist unreserved region may be fully etched off through an etching process, and the remaining photoresist may be removed, so as to form the source electrode 5 and the drain electrode 6 of the TFT at the display region, the source electrode 9 and the drain electrode 10 of the TFT at the GOA region, and the data line.

Through the above-mentioned steps, the TFT at the display region and the TFT at the GOA region may be formed on the base substrate, and then a passivation layer and a pixel electrode may be formed on the base substrate with the TFT at the display region and the TFT at the GOA region, so as to acquire the array substrate.

### Third Embodiment

The method will be described hereinafter in more details by taking the bottom-gate array substrate as an example.

The method in this embodiment may include the following steps.

Step 1: as shown in FIG. 2, providing a base substrate 1, and forming patterns of a gate electrode 2 of the TFT at the display region, a gate electrode 7 of the TFT at the GOA region, and a gate line on the base substrate 1.

The base substrate may be a glass substrate or a quartz substrate. To be specific, a gate metal layer having a thickness of about 500 to 4000 Å may be deposited onto the base substrate 1 through sputtering or thermal evaporation. The gate metal layer may be made of Cu, Al, Ag, Mo, Cr, Nd, Ni, Mn, Ti, Ta, W or an alloy thereof, and it may be of a single-layered structure or a multi-layered structure such as Cu/Mo, Ti/Cu/Ti or Mo/Al/Mo. Next, a photoresist may be applied onto the gate metal layer and then exposed through a mask plate, so as to form a photoresist reserved region corresponding to a region where the patterns of the gate line and the gate electrodes are located and a photoresist unreserved region corresponding a region other than the above region. Next, the photoresist may be developed, so as to fully remove the photoresist at the photoresist unreserved region, and maintain a thickness of the photoresist at the photoresist reserved region. Finally, a gate metal film at the photoresist unreserved region may be fully etched off through an etching process, and the remaining photoresist may be removed, so as to form the patterns of the gate electrode 2 of the TFT at the display region, the gate electrode 7 of the TFT at the GOA region and the gate line.

Step 2: as shown in FIG. 3, forming a gate insulation layer 3 on the base substrate 1 acquired after Step 1.

To be specific, the gate insulation layer 3 having a thickness of about 500 to 5000 Å may be deposited onto the base substrate acquired after Step 1 through Plasma Enhanced Chemical Vapor deposition (PECVD). The gate metal layer 3 may be made of oxide, nitride or oxynitride, and reactive gases may be SiH₄, NH₃ or N₂, or SiH₂Cl₂, NH₃ or N₂.

Step 3: as shown in FIG. 6, depositing a non-metal oxide semiconductor layer onto the gate insulation layer 3, and patterning the non-metal oxide semiconductor layer so as to form an active layer 8 of the TFT at the GOA region.

To be specific, a layer of a non-metal oxide semiconductor material may be deposited onto the gate insulation layer 3, and the non-metal oxide semiconductor material may be p-Si or a-Si. Next, a photoresist may be applied onto the non-metal oxide semiconductor material, and then exposed through a half-tone or grey-tone mask plate, so as to form a photoresist fully-reserved region corresponding to a region where the active layer 8 of the TFT at the GOA region is located, and a photoresist unreserved region corresponding to a region other than the above region. Next, the photoresist may be developed, so as to fully remove the photoresist at the photoresist unreserved region, and maintain a thickness of the photoresist at the photoresist fully-reserved region. Finally, the non-metal oxide semiconductor material at the photoresist unreserved region may be fully etched off through an etching process and remove the remaining photoresist, so as to form a pattern of the active layer 8 of the TFT at the GOA region.

Step 4: as shown in FIG. 5, depositing a metal oxide semiconductor layer onto the gate insulation layer 3, and patterning the metal oxide semiconductor layer so as to form an active layer 4 of the TFT at the display region.

To be specific, a layer of a metal oxide semiconductor material may be deposited onto the gate insulation layer 3, and the metal oxide semiconductor material may be IGZO, IZO, ZnON, CuO or SnO. Next, a photoresist may be applied to the layer of the metal oxide semiconductor material, and then exposed through a half-tone or grey-tone mask plate, so as to form a photoresist fully-reserved region corresponding to a region where the active layer 4 of the TFT at the display region is located, and a photoresist unreserved region corresponding to a region other than the above region. Next, the photoresist may be developed, so as to fully remove the photoresist at the photoresist unreserved region, and maintain a thickness of the photoresist at the photoresist fully-reserved region. Finally, the metal oxide semiconductor material at the photoresist unreserved region may be fully etched off through an etching process, and the remaining photoresist may be removed, so as to form the pattern of the active layer 4 of the TFT at the display region.

Step 5: as shown in FIG. 1, forming a source electrode 5 and a drain electrode 6 of the TFT at the display region and a source electrode 9 and a drain electrode 10 of the TFT at the GOA region and a data line on the base substrate 1 acquired after Step 4.

To be specific, a source-drain metal layer having a thickness of about 2000 to 4000 Å may be deposited onto the base substrate 1 acquired after Step 4 through magnetron sputtering, thermal evaporation or any other film-forming method. The source-drain metal layer may be made of Cu, Al, Ag, Mo, Cr, Nd, Ni, Mn, Ti, Ta or W, or an alloy thereof, and it may be of a single-layered structure or a multi-layered structure such as Cu/Mo, Ti/Cu/Ti or Mo/Al/Mo. Next, a photoresist may be applied to the source-drain metal layer and then exposed through a mask plate, so as to form a photoresist reserved region corresponding to a region where patterns of the source electrodes, the drain electrodes and the data line are located, and a photoresist unreserved region corresponding to a region other than the above region. Next, the photoresist may be developed, so as to fully remove the photoresist at the photoresist unreserved region and maintain a thickness of the photoresist at the photoresist reserved region. Finally, the source-drain metal layer at the photoresist unreserved region may be fully etched off through an etching process, and the remaining photoresist may be removed, so as to form the source electrode 5 and the drain electrode 6 of the TFT at the display region, the source electrode 9 and the drain electrode 10 of the TFT at the GOA region, and the data line.

Through the above-mentioned steps, the TFT at the display region and the TFT at the GOA region may be formed on the base substrate, and then a passivation layer and a pixel electrode may be formed on the base substrate with the TFT at the display region and the TFT at the GOA region, so as to acquire the array substrate.

### Fourth Embodiment

The present disclosure provides in some embodiments an array substrate manufactured by the above-mentioned method. The array substrate includes a display region and a GOA region. An active layer of a first TFT at the display region is made of a metal oxide semiconductor material, and an active layer of a second TFT at the GOA region is made of a non-metal oxide semiconductor material.

According to the array substrate in this embodiment of the present disclosure, the active layer of the TFT at the display region of the array substrate and the active layer of the TFT at the GOA region are made of different materials. To be specific, the active layer of the TFT at the display region of the array substrate is made of the metal oxide semiconductor material. In this way, in the case that a display product has a very high resolution, it is still able to meet a requirement on a charging rate of the high-resolution display product due to high mobility of the metal oxide semiconductor material. The active layer of the TFT at the GOA region of the array substrate is made of the non-metal oxide semiconductor material. In this way, it is able to prevent the occurrence of Vth drift for the TFT due to long-term bias, thereby to prevent a characteristic of the TFT from being varied and ensure a normal scanning function of a GOA unit. Hence, it is able to apply a GOA technology to the high-resolution display device.

In a possible embodiment of the present disclosure, in the case that the array substrate is of a bottom-gate type, it includes: a base substrate; a gate electrode of the first TFT and a gate electrode of the second TFT arranged on the base substrate; a gate insulation layer; the active layer of the first TFT and the active layer of the second TFT arranged on the gate insulation layer; and a source electrode and a drain electrode of the first TFT and a source electrode and a drain electrode of the second TFT.

In a possible embodiment of the present disclosure, as shown in FIG. 7, in the case that the array substrate is of a top-gate type, it includes: a base substrate 1; a buffer layer 11 arranged on the base substrate; the active layer 4 of the first TFT and the active layer 8 of the second TFT arranged on the buffer layer; a source electrode 6 and a drain electrode 4 of the first TFT and a source electrode 10 and a drain electrode 9 of the second TFT; a gate insulation layer 3; and a gate electrode 2 of the first TFT and a gate electrode 7 of the second TFT arranged on the gate insulation layer.

### Fifth Embodiment

The present disclosure provides in this embodiment a display device, including the above-mentioned array substrate. The display device may be a product or member having a display function, such as a liquid crystal television, a liquid crystal display, a digital photo frame, a mobile phone or a flat-panel computer. The display device may further include a flexible circuit board, a printed circuit board and a back plate.

According to the display device in this embodiment of the present disclosure, the active layer of the TFT at the display region of the array substrate and the active layer of the TFT at the GOA region are made of different materials. To be specific, the active layer of the TFT at the display region of the array substrate is made of the metal oxide semiconductor material. In this way, in the case that a display product has a very high resolution, it is still able to meet a requirement on a charging rate of the high-resolution display product due to high mobility of the metal oxide semiconductor material. The active layer of the TFT at the GOA region of the array substrate is made of the non-metal oxide semiconductor material. In this way, it is able to prevent the occurrence of Vth drift for the TFT due to long-term bias, thereby to prevent a characteristic of the TFT from being varied and ensure a normal scanning function of a GOA unit. Hence, it is able to apply a GOA technology to the high-resolution display device.

The above are merely the preferred embodiments of the present disclosure, but the present disclosure is not limited thereto. Obviously, a person skilled in the art may make further modifications and improvements without departing from the spirit of the present disclosure, and these modifications and improvements shall also fall within the scope of the present disclosure.

What is claimed is:

1. A method for manufacturing an array substrate, the array substrate comprising a display region and a Gate Driver on Array (GOA) region, the method comprising steps of:
forming an active layer of a first Thin Film Transistor (TFT) at the display region with a metal oxide semiconductor material; and
forming an active layer of a second TFT at the GOA region with a non-metal oxide semiconductor material.

2. The method according to claim 1, comprising:
providing a base substrate;
depositing a gate metal layer onto the base substrate, and patterning the gate metal layer so as to form a gate electrode of the first TFT and a gate electrode of the second TFT;
forming a gate insulation layer;
depositing a non-metal oxide semiconductor layer onto the gate insulation layer, and patterning the non-metal oxide semiconductor layer to form the active layer of the second TFT;
depositing a metal oxide semiconductor layer onto the gate insulation layer, and patterning the metal oxide semiconductor layer to form the active layer of the first TFT; and
depositing a source-drain metal layer onto the base substrate with the active layer of the first TFT and the active layer of the second TFT, and patterning the source-drain metal layer to form a source electrode and a drain electrode of the first TFT and a source electrode and a drain electrode of the second TFT.

3. The method according to claim 1, comprising:
providing a base substrate;
depositing a gate metal layer onto the base substrate, and patterning the gate metal layer to form a gate electrode of the first TFT and a gate electrode of the second TFT;
forming a gate insulation layer;
depositing a metal oxide semiconductor layer onto the gate insulation layer, and patterning the metal oxide semiconductor layer to form the active layer of the first TFT;
depositing a non-metal oxide semiconductor layer onto the gate insulation layer, and patterning the non-metal oxide semiconductor layer to form the active layer of the second TFT; and
depositing a source-drain metal layer onto the base substrate with the active layer of the first TFT and the active layer of the second TFT, and patterning the source-drain metal layer to form a source electrode and a drain electrode of the first TFT and a source electrode and a drain electrode of the second TFT.

4. The method according to claim 1, comprising:
providing a base substrate;
depositing a buffer layer onto the base substrate;
depositing a non-metal oxide semiconductor layer onto the buffer layer, and patterning the non-metal oxide semiconductor layer to form the active layer of the second TFT;
depositing a metal oxide semiconductor layer onto the buffer layer, and patterning the metal oxide semiconductor layer to form the active layer of the first TFT;
depositing a source-drain metal layer onto the base substrate with the active layer of the first TFT and the active layer of the second TFT, and patterning the source-drain metal layer to form a source electrode and a drain electrode of the first TFT and a source electrode and a drain electrode of the second TFT;
forming a gate insulation layer; and
depositing a gate metal layer onto the gate insulation layer, and patterning the gate metal layer so as to form a gate electrode of the first TFT and a gate electrode of the second TFT.

5. The method according to claim 1, comprising:
providing a base substrate;
depositing a buffer layer onto the base substrate;
depositing a metal oxide semiconductor layer onto the buffer layer, and patterning the metal oxide semiconductor layer to form the active layer of the first TFT;
depositing a non-metal oxide semiconductor layer onto the buffer layer, and patterning the non-metal oxide semiconductor layer to form the active layer of the second TFT;
depositing a source-drain metal layer onto the base substrate with the active layer of the first TFT and the active layer of the second TFT, and patterning the source-drain metal layer to form a source electrode and a drain electrode of the first TFT and a source electrode and a drain electrode of the second TFT;
forming a gate insulation layer; and
depositing a gate metal layer onto the gate insulation layer, and patterning the gate metal layer to form a gate electrode of the first TFT and a gate electrode of the second TFT.

6. The method according to claim 1, wherein the non-metal oxide semiconductor material is polycrystalline silicon (p-Si) or amorphous silicon (a-Si).

7. The method according to claim 1, wherein the metal oxide semiconductor material is indium gallium zinc oxide (IGZO), indium zinc oxide (IZO), zinc oxynitride (ZnON), copper oxide (CuO) or tin oxide (SnO).

8. An array substrate, comprising a display region and a Gate Driver on Array (GOA) region, wherein an active layer of a first Thin Film Transistor (TFT) at the display region is made of a metal oxide semiconductor material, and an active layer of a second TFT at the GOA region is made of a non-metal oxide semiconductor material.

9. The array substrate according to claim 8, comprising:
a base substrate;
a gate electrode of the first TFT and a gate electrode of the second TFT arranged on the base substrate;
a gate insulation layer;
the active layer of the first TFT and the active layer of the second TFT arranged on the gate insulation layer; and
a source electrode and a drain electrode of the first TFT and a source electrode and a drain electrode of the second TFT.

10. The array substrate according to claim 8, comprising:
a base substrate;
a buffer layer arranged on the base substrate;
the active layer of the first TFT and the active layer of the second TFT arranged on the buffer layer;
a source electrode and a drain electrode of the first TFT and a source electrode and a drain electrode of the second TFT;
a gate insulation layer; and
a gate electrode of the first TFT and a gate electrode of the second TFT arranged on the gate insulation layer.

11. The array substrate according to claim 8, wherein the non-metal oxide semiconductor material is polycrystalline silicon (p-Si) or amorphous silicon (a-Si).

12. The array substrate according to claim 8, wherein the metal oxide semiconductor material is indium gallium zinc oxide (IGZO), indium zinc oxide (IZO), zinc oxynitride (ZnON), copper oxide (CuO) or tin oxide (SnO).

13. A display device comprising the array substrate according to claim 8.

14. The display device according to claim 13, wherein the array substrate comprises:
a base substrate;
a gate electrode of the first TFT and a gate electrode of the second TFT arranged on the base substrate;
a gate insulation layer;
the active layer of the first TFT and the active layer of the second TFT arranged on the gate insulation layer; and
a source electrode and a drain electrode of the first TFT and a source electrode and a drain electrode of the second TFT.

15. The display device according to claim 13, wherein the array substrate comprises:
a base substrate;
a buffer layer arranged on the base substrate;
the active layer of the first TFT and the active layer of the second TFT arranged on the buffer layer;
a source electrode and a drain electrode of the first TFT and a source electrode and a drain electrode of the second TFT;
a gate insulation layer; and
a gate electrode of the first TFT and a gate electrode of the second TFT arranged on the gate insulation layer.

16. The display device according to claim 13, wherein the non-metal oxide semiconductor material is polycrystalline silicon (p-Si) or amorphous silicon (a-Si).

17. The display device according to claim 13, wherein the metal oxide semiconductor material is indium gallium zinc oxide (IGZO), indium zinc oxide (IZO), zinc oxynitride (ZnON), copper oxide (CuO) or tin oxide (SnO).
